(19) United States
(12) Patent Application Publication
(10) Pub. No.: US 2007/0066090 A1
(43) Pub. Date: Mar. 22, 2007

(54) Wiring board, process for producing the same polyimide film for use in the wiring board, and etchant for use in the process

(75) Inventors: Kazuhiro Ono, Osaka (JP); Kan Fujihara, Osaka (JP); Kiyokazu Akahori, Osaka (JP)

Correspondence Address: SUGHRUE MION, PLLC, 2100 PENNSYLVANIA AVENUE, N.W., SUITE 800, WASHINGTON, DC, 20037, US

(73) Assignee: KANEKA CORPORATION, Osaka (JP)

(21) Appl. No.: 11/602,958

(22) Filed: Nov. 22, 2006

Related U.S. Application Data
(62) Division of application No. 10/468,445, filed on Aug. 20, 2003.

(30) Foreign Application Priority Data
Feb. 21, 2001 (JP) 2001-045861
Feb. 21, 2001 (JP) 2001-045863

(51) Int. Cl. H01B 13/00; H05K 1/00

(52) U.S. Cl. 439/55; 216/13; 174/250

(57) ABSTRACT

In etching an organic insulating layer made of a polyimide film, a polyimide containing at least a recurrent unit expressed by general formula (1) is used for the polyimide film: 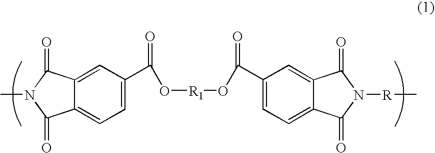 ;and an alkaline etchant containing oxyalkylamine, a hydroxide of an alkaline metal compound, water, and preferably an aliphatic alcohol is used as an etchant. The composition enables efficient formation of desirably shaped via holes and through holes through the organic insulating layer on a wiring board.

### FIELD OF THE INVENTION

The present invention relates to wiring boards suitably used as components in various electronics and their methods of manufacture, as well as polyimide films suitably used on the wiring boards and etchants suitably used according to the methods of manufacture.

### BACKGROUND OF THE INVENTION

Recent years have seen high demands in electronics industry for more capable, functional, and compact electronics. This trend is a cause for the on-going development of IC chip-carrying boards with more densely packed wiring.

An electronic circuit board contains a copper layer (copper-based electric layer) as a typical metal layer and an organic insulating layer made of organic resin as an insulating layer. Conventionally, the organic insulating layer was a polyimide in order to exploit its excellent heat resistance and electrical properties.

What counts in mounting components to these circuit boards, especially printed wiring boards (or printed circuit boards), is the fabrication (formation) of various holes (or openings). Specific examples of holes in the manufacture of a printed wiring board include through holes and via holes, and the technology of forming these holes is very important in the fabrication of a printed wiring board.

In an effort to push the downsizing of the printed circuit board, printed wiring boards with multiple insulating layers, that is, a configuration which provides electrical connections between multiple insulating layers, (“multilayer printed wiring boards” for convenience) are especially popularly used in recent years. With the multilayer printed wiring board, it is required to fabricate fine holes in fabricating the aforementioned various holes such as through holes and via holes. Therefore, in forming such fine holes, more serious problems arise in terms of fabrication profile.

Typically, fabricating a multilayer printed wiring board is said to require such precision to form a through hole or via hole measuring 100 μm or less in diameter, so as to provide connections between the organic insulating layers. It is also required that wiring be formed in such a fine pattern that line widths and space widths are approximately within 20 μm to 50 μm. Therefore, for example, to interpose two to five wires between connecting pads within 150 μm to 500 μm at the foregoing precision, fine holes measuring approximately 20 μm to 30 μm in diameter are required as via holes.

Currently known hole-fabrication technologies are either dry (based on dry process) or wet (based on etching). Dry technology fabricates holes through a mechanical or physical process: e.g., mechanical drilling (using a drill), laser (drilling using laser), plasma dry etching (physical etching using plasma). Wet technology fabricates holes chemically using an etchant that is suited to an organic insulate film material.

Dry technology has following problems in forming fine holes:

First, current mechanical drilling hits a technical limit when used to form via holes measuring less than about 70 μm in diameter, being incapable of forming the aforementioned fine via holes. In addition, if used to form 0.5 mm or smaller fine holes or slits, current mechanical drilling may develop burrs and irregular hole or slit edge profiles and cannot relied upon for high quality holes and slits. Further, the technology requires a lot of labor in keeping a metal mold in good condition and presents obstacles in reducing costs.

Plasma dry etching is very poor in performance (processing speed), capable of forming only a limited number of holes per unit time.

for example, Japanese Laid-open Patent Application 7-297551/1995 or Tokukaihei 7-297551 suggests to use plasma dry etching to form fine holes. According to the technology, each hole is formed so that its interior wall makes an angle of 5° or less to the axis along which the hole is formed. The holes thus formed have superior quality to those formed by mechanical drilling. However, etching a 20-μm-thick organic insulating layer using the technology takes as long as 80 minutes or so.

Processing with laser entails different problems in profile from mechanical drilling.

Specifically, laser processing is more suited to fine fabrication and has a much faster processing speed than mechanical drilling, plasma dry etching, and other like processes, so that laser processing has recently been getting outstanding attention among the dry processes used to form fine holes. For example, Japanese Laid-open Patent Application 60-261685/1985 or Tokukaisho 60-261685 discloses an excimer-laser-based technology to form minuscule via holes and through holes. The technology is capable of delivering fine holes with improved quality and recognized well as an excellent fabrication method.

However, when the excimer-laser-based technology is applied to form a hole through an organic insulating layer on a multilayer printed wiring board, the resultant hole narrows down toward the front end, that is, toward the bottom (far end) of the hole. More specifically, the hole tapers off, with the interior wall at an angle to the axis along which the hole is formed. Supposing that the hole formed is a via hole, such a tapering profile imparts large resistance to the via hole.

Attempts to ensure a predefined diameter at the bottom of the via hole inevitably result in adding an extra value to the rear end diameter (diameter on the near end of the hole formed or on the upper end when viewed from the bottom). Less area will be available for wiring pattern on the surface of the organic insulating layer, which presents an obstacle in designing a high density wiring pattern.

Wet technology is commonly used to form through holes, via holes, and like holes, because it has advantages over dry technology in terms of equipment and other costs of forming those holes (cost of equipment) and performance (etching speed).

Wet technology also has problems as follows, in forming fine holes:

Typical wet methods often employs alkaline etching in which an alkaline solution is used as an etchant.

For example, Japanese Laid-open Patent Application 3-101228/1991 or Tokukaihei 3-101228 discloses a technology whereby an etchant composed of hydrazine monohydrate and potassium hydroxide is applied; and Japanese Laid-open Patent Application 5-202206/1993 or Tokukaihei 5-202206 discloses a technology whereby an etchant composed of sodium hydroxide, ethylenediamine, hydrazine monohydrate, a dimethylamine solution, and N,N-dimethylformamide.

These hydrazine-containing etchants (hydrazine etchants) have short a short lifespan (liquid life) during which the etchants remain efficacious; the short term validity makes it difficult to use them in etching in optimized conditions. Besides, the etchants themselves are toxic (may cause cancer).

In etching, a mask of a predefined pattern which corresponds to holes is placed on the surface of a polyimide film (organic insulating layer) so as to form holes in the predefined pattern on the polyimide film. A copper layer formed in a predefined pattern may be used as the mask if the printed wiring board to be etched is made by stacking a polyimide film and a copper layer.

The hydrazine etchants readily infiltrate between the mask and the polyimide film. Accordingly, with the copper layer on the polyimide film being used as the mask, the etching with any of the etchants results in the copper layer peeling off the polyimide film before holes are formed through the polyimide film, and is likely to fail to form desired holes.

Japanese Laid-open Patent Application 60-14776/1985 or Tokukaisho 60-14776 discloses other etchants including those composed of urea and an alkaline metal compound.

Those etchants are significantly inferior to the hydrazine etchants noted earlier in etching speed and likely to etch out deformed holes (having a profile and dimensions which do not conform to predefined conditions). Further, if etching temperature is set to a higher value to speed up etching, the urea decomposes and produces ammonium which has irritating odor. Results may be environmental health issues and grossly shortened liquid life, which render the use of the etchants hardly practical.

Let us take, as two more examples, those etchants which are disclosed in Japanese Laid-open Patent Application 7-157560/1995 or Tokukaihei 7-157560. These are dimethylformamide solutions containing ethanolamine and can etch polyimide away which is insoluble in organic solvents only with difficulties.

Japanese Laid-open Patent Application 10-195214/1998 or Tokukaihei 10-195214 gives a further example of etchant. The etchant contains an aliphatic alcohol, oxyalkylamine, an alkaline metal compound, and water. The etchant is made suitable for the purpose of dissolving commercially available, alkali-resistant photoresist materials (FSR-220, a product of Fuji Chemical Co. Ltd., is an example) and therefore readily infiltrate between polyimide and the alkali-resistant photoresist material, making it difficult to deliver a desired etching profile.

As detailed in the foregoing, both dry and wet technology has shortcomings and has issues waiting to be solved to apply to the multilayer printed wiring board. This is especially true when the technology is used in etching an organic insulating layer made of a polyimide to efficiently form via holes and through holes with a desired profile.

In order to address these problems, the present invention has an objective to offer a wiring board, having an organic insulating layer made of a polyimide, which enables efficient formation of via holes and through holes with a desired profile; a method of manufacturing such a wiring board; a polyimide film used on the wiring board; and an etchant suitably used according to the method of manufacturing the wiring board.

### DISCLOSURE OF THE INVENTION

Through continuous effort to achieve these objectives, the inventors of the present invention have found out that the use of an etchant of a particular composition makes it possible to extremely efficiently form holes in a desired shape with no edge profile deformation through an organic insulating layer made of a polyimide, which has brought the present invention to completion.

The method of manufacturing a wiring board of the present invention, to solve the problems, is characterized in that it includes the etching step of etching an organic insulating layer,

wherein:

the organic insulating layer is a polyimide film made of a polyimide containing at least a recurrent unit expressed by general formula (1) 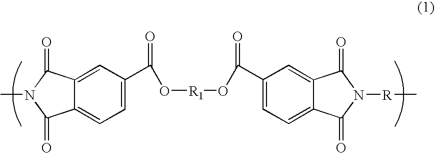
where R1 is an aromatic structure containing a benzene ring or a naphthalene ring and R is an aromatic structure containing a benzene ring; and

for the etching, an etchant is used which contains oxyalkylamine, a hydroxide of an alkaline metal compound, and water.

Preferably, the etchant further contains an aliphatic alcohol. More preferably, the polyimide film is subjected to corona processing and/or plasma processing.

The method enables extremely efficient formation of holes in desired shapes with no edge profile deformation through an organic insulating layer made of a polyimide. Therefore, efficient formation of holes, such as via holes and through holes, in desired shapes through an organic insulating layer on a wiring board becomes possible, and high quality wiring boards can be manufactured.

Alternatively, the method of manufacturing a wiring board of the present invention may be a method including the etching step of etching an organic insulating layer, wherein:

the organic insulating layer is a polyimide film;

the polyimide film has at least any one of following properties: a water absorbency of not more than 2.0%, a linear swelling coefficient of not more than 20 ppm/° C. in a temperature range of 100° C. to 200° C., a moisture-absorption swelling coefficient of not more than 10 ppm/% RH, an elastic modulus of 4.0 to 8.0 GPa, and a tension elongation ratio of not less than 20%; and

for the etching, an etchant is used which contains oxyalkylamine, a hydroxide of an alkaline metal compound, and water.

Further, the method of manufacturing a wiring board of the present invention may be a method including the etching step of etching an organic insulating layer,

wherein:

the organic insulating layer is a polyimide film;

for the etching, an etchant is used which contains oxyalkylamine, a hydroxide of an alkaline metal compound, and water; and

a metal layer made of at least any one of copper, chromium, and nickel is used as a mask in the etching. Under this circumstance, preferably, the metal layer used as the mask is formed directly on a surface of the polyimide film.

The wiring board of the present invention, to solve the problems, is characterized in that it includes at least an organic insulating layer and a metal wiring layer,

wherein the organic insulating layer has an opening with a wall having a taper angle of not more than 45°, preferably not more than 5°, with respect to an axis of the opening.

The arrangement is capable of extremely efficiently forming holes in desired shapes with no edge profile deformation through an organic insulating layer made of a polyimide. Therefore, high quality wiring boards can be offered which allow efficient formation of holes, such as via holes and through holes, in desired shapes through an organic insulating layer on the wiring boards.

Alternatively, the wiring board of the present invention may be a wiring board for flexible printing, prepared by etching a polyimide film using an etchant containing at least, water, an aliphatic alcohol, 2-ethanolamine, and an alkaline metal compound,

the wiring board meeting following conditions:

(1) a wall of an opening formed has a taper angle of not more than 45° with respect to an axis of the opening;

(2) in the opening, an edge profile deformation is not as long as the polyimide film is thick; and

(3) when two or more of the opening are formed in a circular shape measuring 0.5 mm in diameter, in not more than 5 of the openings, an edge profile deformation is not less than 10% as long as the polyimide film is thick.

An etchant of the present invention, to solve the problems, is characterized in that it is for etching a polyimide, provided on a board as an organic insulating layer, containing at least a recurrent unit expressed by general formula (1), and that it includes oxyalkylamine, a hydroxide of an alkaline metal compound, and water.

Preferably, the etchant includes an aliphatic alcohol.

The arrangement makes it possible to extremely efficiently form holes in desired shapes with no edge profile deformation through the organic insulating layer made of a polyimide in manufacturing a wiring board. Therefore, efficient formation of holes, such as via holes and through holes, in desired shapes through an organic insulating layer on a wiring board becomes possible, and high quality wiring boards can be manufactured.

For a fuller understanding of the nature and advantages of the invention, reference should be made to the ensuing detailed description taken in conjunction with the accompanying drawings.

### BRIEF DESCRIPTION OF DRAWINGS

FIG. 1 is a schematic drawing illustrating the formation of a hole by etching, in accordance with a method of manufacturing a wiring board of the present invention.

FIG. 2 is a cross-sectional view illustrating a hole on a wiring board of the present invention and its neighborhood.

FIG. 3 is a schematic drawing showing a measuring instrument which measures a moisture-absorption swelling coefficient of a polyimide film used on a wiring board of the present invention.

FIG. 4 is a graphical representation of humidity changes under which measurements are made using the measuring instrument shown in FIG. 3.

FIG. 5 is a schematic drawing illustrating a hole formed by etching, as observed from above using a microscope.

### BEST MODE FOR CARRYING OUT THE INVENTION

The following will describe an embodiment of the present invention and is by no means intended to limit the scope of the present invention.

A wiring board of the present invention has at least an organic insulating layer and a metal wiring layer and is provided on the wiring board with openings (holes) formed so that each opening has a wall which makes an angle (taper angle) of 45° or less to the axis of the opening; preferably, the taper angle is 5° or less and the organic insulating layer is a polyimide.

A method of manufacturing a wiring board of the present invention forms openings with the aforementioned profile through the organic insulating layer using an alkaline etching method; it is extremely preferred if the organic insulating layer is a polyimide, in which event a polyimide film may be used as the organic insulating layer. An etchant (alkaline etchant) used contains, for example, at least water, oxyalkylamine, and a hydroxide of an alkaline metal compound and preferably contains an aliphatic alcohol.

It is extremely preferred if a polyimide film of the present invention for use on the wiring board is made of a polyimide which meets the following conditions when etched using the etchant: (i) The opening wall has a taper angle of 45° or less to the axis of the opening. (ii) Edge profile deformation in etching is smaller than the resin thickness. (iii) Edge profile deformation occurs at 5 or less positions in a circular opening measuring 0.5 mm in diameter. The above-noted etchant of the present invention used in accordance with a method of manufacturing a wiring board contains the above-noted components and its composition is optimized for the etching of the polyimide film.

The wiring board of the present invention is suitably used as a flexible printed wiring board among other applications.

Referring to FIG. 2, the wiring board of the present invention has at least an organic insulating layer 2 and a metal layer 4 stacked thereon. As will be discussed later in detail, the metal layer 4 is formed as a metal wiring layer having a predefined pattern. Being made of at least a polyimide, the organic insulating layer 2 is specifically a polyimide film.

Although not shown in the figure, the metal layer 4 may be attached to the organic insulating layer (polyimide film) 2 using an adhesive or directly placed thereon without any adhesive. The wiring board of the present invention may therefore has an adhesive layer, as well as other kinds of layers including, for example, a base layer providing support to the organic insulating layer 2. There may be provided an additional organic insulating layer or layers 2 and an additional metal layer or layers (metal wiring layer or layers) 4. The multilayer structure of the wiring board of the present invention is configured as necessary, depending on its purpose and not limited in any manner.

Throughout the following discussion, the wiring board with only the organic insulating layer 2 and the metal layer 4 shown in FIG. 2 is taken as an example for ease of describing the present invention; the present invention is however by no means limited to the example.

A wiring board configured as above is manufactured as follows: First, form an organic insulating layer (polyimide film) 2, and then deposit (stack) a metal layer 4 on at least one, preferably both, of the surfaces of the organic insulating layer 2. The organic insulating layer 2 and the metal layer(s) 4 thus combined will be hereinafter referred to as a stacked layer entity.

Following the formation of the stacked layer entity, carry out etching by, for example, common photolithography using a ferric chloride solution or another etchant to produce a predefined shape (for example, a diameter of 500 μm), so as to reveal a surface of the organic insulating layer 2 (not shown). The metal layer 4 now is constituting a metal wiring layer of a predefined pattern. Subsequently, etch out desired holes (openings) 3, such as via holes or through holes, through the organic insulating layer 2 by alkaline etching.

A method of manufacturing a wiring board of the present invention therefore includes at least an organic-insulating-layer-forming step of forming a polyimide film as the organic insulating layer 2 and an etching step of etching the organic insulating layer 2 to form via holes or other kinds of holes 3. It is preferred if the manufacturing method of the present invention includes a metal-layer-forming step of forming a metal layer 4 on a surface of the organic insulating layer 2 and a metal-wiring-layer-fabricating step of fabricating the metal layer 4 into a metal wiring layer of a predefined pattern.

Regarding the wiring board of the present invention and its method of manufacturing, the metal layer 4 is formed on a surface of the organic insulating layer 2 in the metal-layer-forming step is not limited in any particular manner. Specifically, for example, any of the following methods can be applied:

(1) Attach the metal layer 4 to the organic insulating layer 2 using adhesive. According to the method, a stacked layer entity is formed which includes a structure in which the organic insulating layer 2, an adhesive (or adhesive material), and the metal layer 4 are stacked in this layer. This method will be referred to as an adhesive method for convenience. Examples of the adhesive include commonly known and used acrylic, phenol, epoxy, and polyimide resins: polyimide adhesives are especially preferred.

The adhesive method is further discussed assuming that the adhesive is a polyimide resin as an example. In a specific example of the method, a copper or other metal foil is attached to a polyimide stacked layer entity: the polyimide stacked layer entity is a polyimide base film provided on either one or both of its surfaces with a layer of polyimide adhesive or polyamide adhesive which is a polyimide precursor and prepared by, for example, a prior art method disclosed in Japanese Patent Application 10-309620/1998 or Tokuganhei 10-309620 (Japanese Laid-open Patent Application or Tokukai 2000-129228).

More specifically, the polyimide stacked layer entity can be formed by either (i) applying a polyamic-acid polymer solution onto a base film and thereafter form an imide from it or (ii) applying a polyimide dissolved in an organic solvent onto a base film and drying it. A further alternative is forming a film of a polyamic-acid or polyimide which will be an adhesive and attaching it to a base film.

It is not limited in any particular manner how a metal foil or foils may be adhered to the polyimide stacked layer entity: for example, place a metal foil on an adhesive layer formed on either one or both of the surfaces of the polyimide stacked layer entity and insert them between a pair of heated rollers or in a vacuum mold pressing machine for thermocompression; alternatively, directly apply or thermocompress a layer of adhesive onto a metal foil and thermocompress them to a base film.

(2) Form the metal layer 4 directly on a surface of the organic insulating layer 2 with no intervening adhesive layer. This method will be referred to as a direct method for convenience. Specific examples of methods of forming the metal layer 4 used in the direct method include methods, such as vapor deposition, sputtering, and ion plating, which are capable of forming an extremely thin metal coating (“thin film forming methods,” for convenience); and plating-based forming methods, such as electroless plating and electroplating.

(3) Stack the organic insulating layer 2 on the metal layer 4 through painting or coating of a surface of a metal foil with a solution of an organic insulator. This method will be referred to as an organic-insulating-layer coating method for convenience.

Specifically, apply a polyimide dissolved in an organic solvent and a polyamic-acid dissolved in an organic solvent on a conductive metal foil and dry/heat it; to do this, prior art technologies are available as disclosed in, for example, Japanese Laid-open Patent Application 56-23791/1981 or Tokukaisho 56-23791, Japanese Laid-open Patent Application 63-84188/1988 or Tokukaisho 63-84188, and Japanese Laid-open Patent Application 10-323935/1998 or Tokukaihei 10-323935. A stacked layer entity results which includes the metal layer 4 of a conductive metal foil and the organic insulating layer 2 of a polyimide.

Any one of methods (1) to (3) may be employed in the present invention: however, method (2), or a direct method, is preferred to the others because of its productivity and advantages in etching of the organic insulating layer 2.

Note that some adhesives may dissolve in method (1), or an adhesive method, but not in the other two methods, depending on the etchant used to etch the organic insulating layer 2. If an adhesive other than polyimide-based ones is used, the shape of the resultant hole 3 may be unpredictable and unsuited to the present invention.

Now, the metal layer 4 will be described. As will be discussed later in detail, the metal layer 4 is etched in a predefined pattern and functions as a metal wiring layer. Considering this, suitable materials for the metal layer 4 are metals, including those various, commonly known and used metals, which can be used as metal wiring depending on the usage of the wiring board.

The material for the metal layer 4 is not limited in any particular manner. Typical suitable examples include metals, such as copper, chromium, nickel, aluminum, titanium, palladium, silver, tin, vanadium, zinc, manganese, cobalt, and zirconium; any one of the listed metals may be used alone, or alternatively two, or more of them may be used together in any combination as an alloy where necessary. Especially preferable metals among those listed are copper, iron, vanadium, titanium, chromium, and nickel; it is preferred if two or more of these metals are chosen for use as an alloy depending on conditions.

The metal layer 4 may be either a single layer or a multilayer metal film in which multiple layers are stacked. Specifically, for example, a double-layer metal layer 4 is obtainable by forming an extremely thin metal coating (first metal layer) on the organic insulating layer 2 and then forming a conductive layer metal coating (second metal layer) on the first metal layer.

Further, in the present invention, as will be discussed later in detail, the metal layer 4 plays two roles as an alkali-resistant mask layer and a metal wiring layer; therefore, preferably, at least a conductive layer suitable as a metal wiring layer is included. With a double-layer arrangement, the conductive, second metal layer is preferable in terms of properties of the wiring board.

As will be detailed later, when subjected to etching into a predefined pattern and other steps, the metal layer 4 arranged as above is suitably used as a metal wiring layer and also as a mask layer in alkaline etching the organic insulating layer 2 which is formed under the metal layer (metal wiring layer) 4.

The foregoing various metallic materials are preferred to form a mask and can be used as a conductive layer too. Among them, copper is especially preferred as a material for a conductive layer, i.e., metal wiring layer. A copper metal layer 4 may be formed by a thin film forming method or plating-based forming method described in relation to method (2), or a direct method, or may be formed in advance as a conductive metal foil. The conductive metal foil is, for example, electrolytic copper foil and rolled copper foil, but not limited in any particular manner. The thickness of the conductive metal foil is not limited in any particular manner, but generally preferably in a range from not more than 5 μm to not less than 35 μm.

The formation pattern of the metal layer 4 of the present invention is not limited in any particular manner. Five examples will be described below:

A first pattern is formed by forming a first metal layer on a polyimide film by a thin film forming method and a second metal layer on the first metal layer by a plating-based forming method.

In the first pattern, the thickness of the first metal layer is not limited in any particular manner, but preferably, for example, in a range of not less than 50 Å and not more than 20,000 Å. Further, the first metal layer may be either a single layer or has a multilayer structure constituted by two or more layers. With a double-layer structure, preferably, for example, a first layer in the first metal layer has a thickness in a range of not less than 50 Å and not more than 1,000 Å, whilst a second layer in the first metal layer has a thickness of not less than 50 Å and not more than 10,000 Å.

In the first pattern, the thickness of the second metal layer is not limited in any particular manner. As explained in relation to the conductive layer, typically, preferably, it has a thickness of not less than 5 μm and not more than 35 μm.

A second pattern is formed by forming a first metal layer on a polyimide film by a thin film forming method and a second metal layer on the first metal layer by a thin film forming method, so both the first metal layer and the second metal layer are fabricated by a thin film forming method such as vapor deposition, sputtering, or ion plating.

In the second pattern also, the thickness of the first metal layer is not limited in any particular manner, but preferably, for example, in a range of not less than 50 Å and not more than 20,000 Å. As in the first pattern, the first metal layer may have a multilayer structure. Further, in the second pattern, the thickness of the second metal layer is again not limited in any particular manner; however, as explained in relation to the conductive layer, typically, preferably, it has a thickness of not less than 5 μm and not more than 35 μm.

In the present invention, the metal layer 4 (the first/second metal layer) is preferably thin; if it is too thick, a metal wiring layer cannot be formed in a fine pattern. Specifically, as will be discussed later in detail, the present invention has a step of etching the metal layer 4 to form a metal wiring layer in a predefined pattern; the metal wiring layer etched in this step naturally comes to have a taper angle. In the metal wiring layer, a fine pattern is required where the line width and the space width are between 20 μm to 50 μm. However, when a taper angle is present, such a fine pattern is not obtainable. Therefore, the thickness of the metal layer 4 is preferably within the aforementioned range.

A third pattern is formed by applying a polyimide dissolved in an organic solvent or a polyamic-acid dissolved in an organic solvent on a conductive metal foil and drying/heating it. The metal layer 4 formed by method (3), or an organic-insulating-layer coating method falls in this category. The conductive metal foil used in the third pattern is suitably the foregoing copper foil. The thickness of the copper foil is again preferably in a range of not less than 5 μm and not more than 35 μm as mentioned earlier.

A fourth pattern is formed by attaching a polyimide stacked layer entity to a conductive metal foil such as a copper foil. The metal layer 4 formed by method (1), or an adhesive method, falls in this category.

A final, fifth pattern is the metal layer 4 formed directly on a polyimide film by electroless plating, that is, one of plating-based forming methods in method (2), or a direct method.

In the first/second patterns, the second metal layer is preferably copper as mentioned earlier. An example of the first metal layer is a chromium film. A chromium film can be formed by vapor deposition in a condition of 3×10⁻³ Torr or less, preferably 5×10⁻³ Torr or less. The chromium film can be suitably used, especially, as an alkali-resistant mask layer. The copper layer, if formed by the thin film forming method, is preferably formed in a condition of 1×10⁻³ Torr or less.

Therefore, a preferred example of the stacked layer entity of the present invention is an arrangement in which the organic insulating layer 2, a chromium layer, and a copper layer are stacked in this order. In other words, the example is an arrangement in which the metal layer 4 is a double layer arrangement including a chromium layer which is the first metal layer and a copper layer which is the second metal layer, with the chromium layer directly stacked on the organic insulating layer 2. Preferably, the chromium layer has an interface for the organic insulating layer 2 and its thickness is in a range of 100 Å to 3000 Å. The thickness of the copper layer is preferably in a range of not less than 1 μm and not more than 50 μm.

In a method of manufacturing a wiring board of the present invention, to directly form the metal layer 4 on the organic insulating layer 2 (to form the metal layer 4 by method (2), or a direct method), before the metal layer 4 is formed, the organic insulating layer 2 preferably is subjected to corona processing and/or plasma processing.

In alkaline etching the organic insulating layer 2 which will be detailed later, the resultant pattern does not have smooth etched edges and edge profile deformation is likely to occur. The edge profile deformation is presumably due to etchant reaching an interface between the organic insulating layer 2 and the metal layer 4 (metal wiring layer).

In the manufacturing method of the present invention, edge profile deformation is satisfactorily avoidable because an etching method (will be detailed later); carrying out corona processing or plasma processing is preferred, since it is better ensured for some unknown reason that edge profile deformation is avoided.

The corona processing and/or the plasma processing on the organic insulating layer 2 may be commonly known and used method and is not limited in any particular manner.

The corona processing may be carried out using a generic corona processing machine available in the industry. Attention should be paid to corona processing density which is preferably in a range of not less than 50 W·min/m² and not more than 800 W·min/m². Corona processing density is calculated by the following formula (1):
Corona Processing Density (W·min/m²)=Corona output (W)/{Line Speed (m/min)×process width (m)} (1)

The plasma processing may be also carried out using a generic plasma processing machine available in the industry. The plasma processing may be carried out under a reduced pressure or atmospheric pressure. Discharge under atmospheric pressure is preferred in terms of processing facilities cost.

The plasma processing under atmospheric pressure is not limited in any particular manner; gases suitably used in the plasma processing includes inert gases, such as helium, argon, krypton, xenon, neon, radon, and nitrogen: and oxygen; air; carbon oxide; carbon dioxide; carbon tetrachloride; chloroform; hydrogen; ammonium; and trifluoromethane. Any one of the gases may be used alone, or alternatively two or more of them may be used together as a gas mixture in any combination. Further, commonly known gas fluorides may be used.

If two or more of the gases are used together, preferred combinations include argon/oxygen, argon/helium/oxygen, argon/carbon dioxide, argon/nitrogen/carbon dioxide, argon/nitrogen/helium, argon/nitrogen/carbon dioxide/helium, argon/helium, and argon/helium/acetone.

In the present invention, the order in which the corona processing and the plasma processing are carried out is not limited in any particular manner; however, to better avoid edge profile deformation, preferably, the corona processing is carried out on the organic insulating layer 2, which is followed by the plasma processing.

In the method of manufacturing a wiring board of the present invention, as mentioned in the foregoing, the metal layer 4 is formed as a metal wiring layer having a predefined circuit pattern in the metal-wiring-layer-fabricating step. The metal-wiring-layer-fabricating step is not limited in any particular manner and may be, for example, a commonly known and used method, such as a subtractive method, an additive method, or a semi-additive method.

The predefined circuit pattern of the metal wiring layer is not limited in any particular manner and may be any circuit pattern so long as it is suited to the purposes of the wiring board of the present invention. Accordingly, the same goes with the mask used in the metal-wiring-layer-fabricating step of the present invention as long as it has the suitable circuit pattern. Note that in the present invention the mask preferably has an etching pattern to etch polyimide, especially, a hole pattern to form holes, because the metal wiring layer doubles as an alkali-resistant mask in etching polyimide as mentioned in the foregoing.

Now, the organic insulating layer 2 will be described. The wiring board of the present invention is suitably used, for example, flexible printed wiring board (“FPC”) and tape automated bonding (“TAB”). Therefore, the organic insulating layer 2 of the present invention can be suitably used for, for example, FPC base films and TAB film carrier. When the wiring board is to be used for FPC or TAB, hopefully the organic insulating layer 2 has a sufficiently high elastic modulus, a low moisture-absorption swelling coefficient, and a low linear swelling coefficient.

If the organic insulating layer 2 has a high moisture-absorption swelling coefficient or linear swelling coefficient, an FPC fabricated from the organic insulating layer 2 warps or curls when there is a change in an operating environment, i.e., temperature, humidity, etc. Especially, relatively large-area FPCs, like those used in PDPs (plasma displays), require high stability in precision of the base film.

Therefore, in the FPCs and the like, an organic insulator 2 which has heat resistance, a sufficient elastic modulus, flexibility, a sufficient linear swelling coefficient, and a sufficient moisture-absorption swelling coefficient is preferably used as an organic insulator constituting the organic insulating layer 2. A specific example is a film of polyimide.

Among the properties of polyimide film, the elastic modulus, the linear swelling coefficient, the moisture-absorption swelling coefficient, and the water absorbency will be discussed in terms of their preferred ranges.

The elastic modulus of the polyimide film, when the polyimide film is used as a base film for a FPC, is preferably in a range of more than 4.0 GPa and not more than 10 GPa, more preferably in a range of not less than 5.0 GPa and not more than 10 GPa, and even more preferably in a range of 5.0 GPa to 9.0 GPa.

Elastic moduli above 10 GPa are not preferred, since such values make the polyimide film too rigid and difficult to handle when the FPC must be foldable in mounting. Those less than, or equal to, 4.0 GPa are not preferred either, since such values make the polyimide film too soft and poor in workability: for example, wrinkles might develop in roll-to-roll processing. The wrinkles that develop in roll-to-roll processing carried out in a vacuum chamber is a great problem, especially when a copper layer as a metal layer is directly stacked on the polyimide film with no adhesive in between (method (2), or direct method), irrespective of whether sputtering or vapor deposition is employed. Therefore, elastic moduli less than, or equal to, 4.0 GPa are not preferred.

The polyimide film, when used as an FPC base film, has a linear swelling coefficient of not more than 20 ppm/° C., preferably not more than 18 ppm/° C., and more preferably not more than 15 ppm/° C., in a range of 100° C. to 200° C. as measured by TMA.

Similarly, the polyimide film, when used as an FPC base film, has a moisture-absorption swelling coefficient of not more than 15 ppm/% RH, preferably not more than 12 ppm/% RH, and more preferably not more than 10 ppm/% RH, as measured by the measuring method disclosed in Japanese Patent Application 11-312592/1999 or Tokuganhei 11-312592 (Japanese Laid-open Patent Application 2001-72781 or Tokukai 2001-72781).

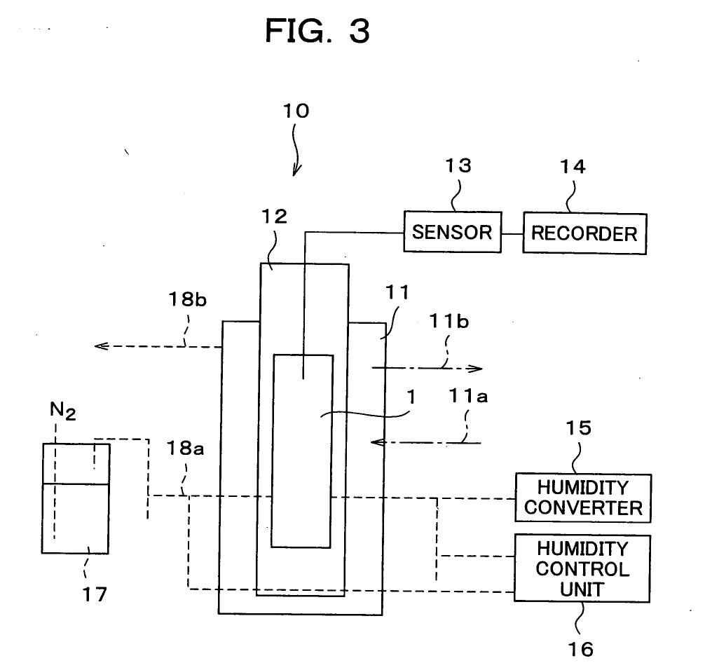

Specifically, as schematically shown in FIG. 3, a measuring instrument 10 which measuring the moisture-absorption swelling coefficient is equipped with a hot water tank 11, hot water pipes 11a, 11b, a thermostatic layer 12, a sensor 13, a recorder 14, a humidity converter 15, a humidity control unit 16, a water vapor generator 17, and water vapor pipes 18a, 18b.

The hot water tank 11 is for adjusting the measuring temperature at which the moisture-absorption swelling coefficient is measured. The temperature adjustment is carried out by means of hot water which flows in through the hot water pipe 11a and out through the hot water pipe 11b as indicated by arrow heads in the figure. The pipes 11a and 11b are indicated by alternate long and short dash lines in the figure.

The thermostatic tank 12 is provided inside the hot water tank 11 and connects to the humidity converter 15, the humidity control unit 16, and the water vapor generator 17 via the water vapor pipes 18. Humidity in the thermostatic tank 12 can be increased with sample 1, i.e., a wiring board of the present invention loaded.

The sensor 13 is for measuring an elongation of sample 1 and may be any commonly known and used sensor. The recorder 14 is for recording the elongation detected by the sensor 13 and may be any commonly known and used recorder.

The humidity converter 15 and the humidity control unit 16 are for controlling humidity conditions in the thermostatic tank 12, and specifically, adjust them by heating a mantle heater (not shown) according to a program. The thermostatic layer 12 is equipped with a humidity sensor (not shown). The humidity sensor adjusts sensor temperature so that it equals the temperature of the thermostatic tank 12. There is a temperature adjustment position outside the thermostatic tank 12, on a sensor body.

The water vapor generator 17 is for producing water vapor by introducing nitrogen through the pipe identified as N₂ in the figure and introducing the vapor into the thermostatic tank 12 by means of the humidity converter 15 and humidity control unit 16 through the water vapor pipe 18a depicted by a dotted line for humidification. The temperature of the thermostatic tank 12 is also adjusted to prevent dew from forming. The water vapor pipe 18b is provided to allow water vapor to flow out.

The hot water tank 11, the hot water pipes 111a, 11b, the thermostatic layer 12, the sensor 13, the recorder 14, the humidity converter 15, the humidity control unit 16, the water vapor generator 17, the water vapor pipes 18a, 18b, the humidity sensor, etc. are not limited in any particular manner in terms of their specific arrangements and may be any commonly known and used tank.

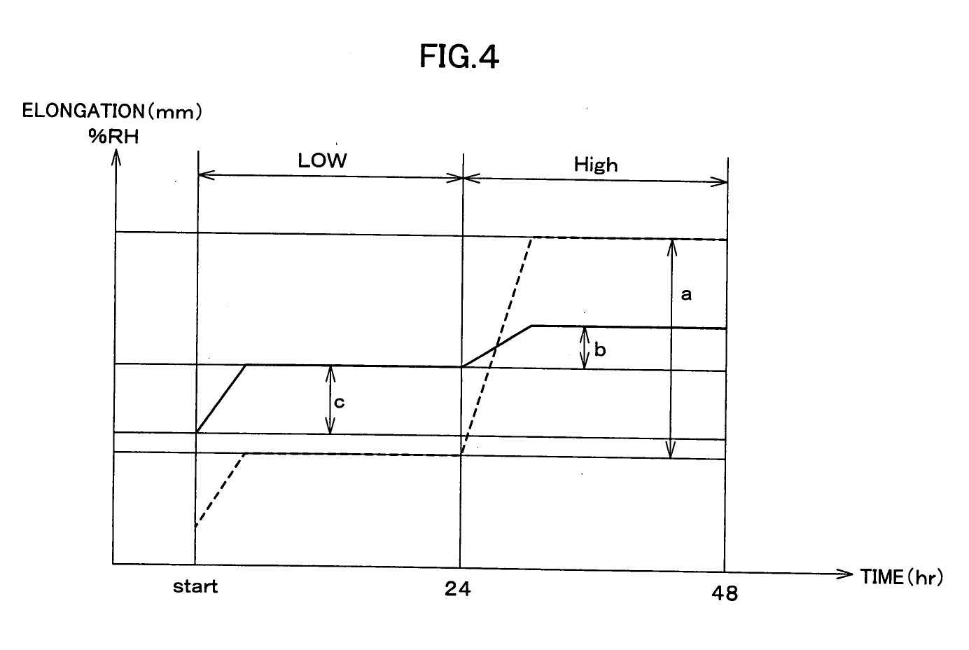

Conditions will be now discussed under which humidity varies during measurement of the moisture-absorption swelling coefficient using the measuring instrument 10. In FIG. 4, the axis of ordinate represents humidity in RH % and elongation of polyimide film in millimeters, whereas the axis of abscissas represents time in hours. At a predefined measuring temperature, the ambient humidity of the polyimide film is varied from low (“LOW” in the figure) to high (“High” in the figure) as indicated by dotted lines; variations in humidity and elongations of the polyimide film (indicated by solid lines in the figure) were measured simultaneously.

In FIG. 4, “a” represents a humidity variation, “b” a moisture absorption elongation of a polyimide film (sample 1), and “c” a thermal swell taking place by the time temperature increases from room temperature to measuring temperature after the installation of sample 1. A humidity elongation ratio is given by formula (2):
Moisture-absorption Swelling Coefficient (ppm/% RH)={b/(Length of Sample+c)}/a (2)

When used as a base film for a FPC, the polyimide film has a water absorbency of 2.0% or less, preferably 1.5% or less. The water absorbency is given by formula (3):
Water Absorbency (%)=(W2−W1)/W1×100 (3)

where W1 is the weight of the film which has been dried at a predefined temperature for a predefined period of time, and W2 is the weight of the film which has been dipped in distilled water for 24 hours and wiped to remove water drops from its surface.

Variations in size of the FPC itself, i.e., variations in size due to the swelling caused by heat and moisture absorption can be constrained if the linear swelling coefficient, the moisture-absorption swelling coefficient, and the water absorbency are confined within the ranges detailed above. The lower limits of the linear swelling coefficient, the moisture-absorption swelling coefficient, and the water absorbency are not limited in any particular manner; reducing the variations in size can be achieved by considering only their upper limits.

Specific examples of polyimide films which are suitably used in FPCs, among those which exhibit the aforementioned properties, i.e., the present invention, are those made of polyimides in which a unit expressed by general formula (1) appears recurrently in molecules:

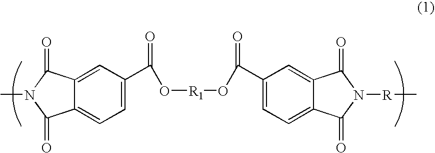

where R1 is an aromatic structure containing a benzene ring or a naphthalene ring and R an aromatic structure containing a benzene ring.

In those polyimides, R1 in general formula (1) is 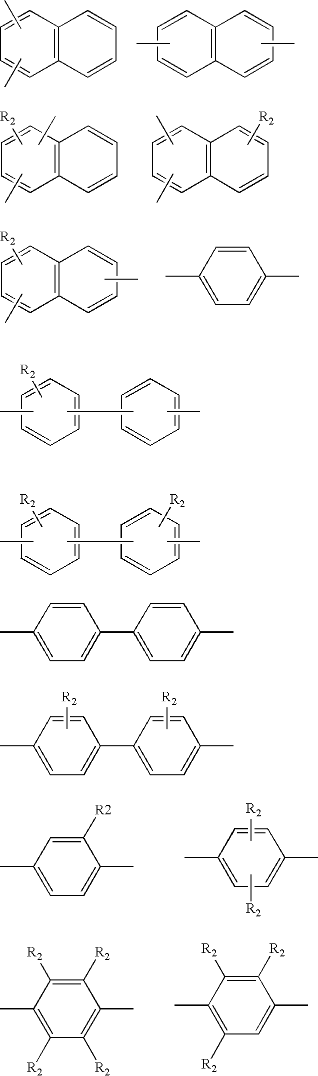
and —CH₃O; and R is a divalent organic group expressed by

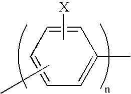

where n is one of integers, 1, 2, and 3, and X is any monovalent substituent selected from the group consisting of hydrogen, halogen, a carboxyl group, a lower alkyl group having 6 or less carbons, and a lower alcoxy group having 6 or less carbons; and/or

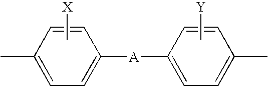

where each of Y and Z is any monovalent substituent selected from the group consisting of hydrogen, halogen, a carboxyl group, a lower alkyl group having 6 or less carbons, and a lower alcoxy group having 6 or less carbons, Y and Z may be either identical or different, and A is any divalent linking group selected from the group consisting of —O—, —S—, —CO—, —SO₂—, and —CH₂—.

Further, the polyimides preferably contain, in addition to the unit expressed by general formula (1), a unit expressed by general formula (2) which appears recurrently in molecules:

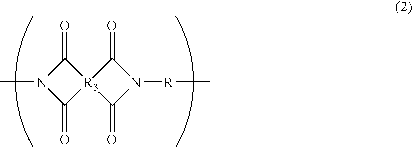

where R is identical to R in general formula (1), and R3 is a tetravalent organic group selected from:

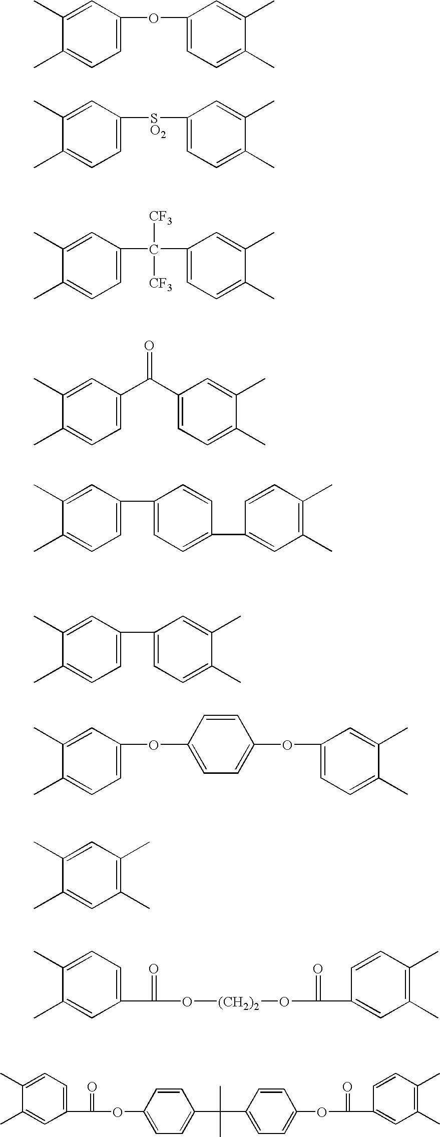

Further, in the polyimides, it is more preferred if the recurrent unit expressed by general formula (1) is expressed by general formula (3)

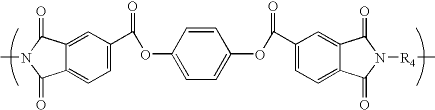

where R₄ is a divalent organic group selected from: 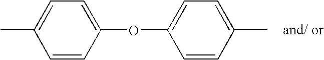
and/or

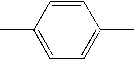

Further, in the polyimides, it is more preferred if the recurrent unit expressed by general formula (2) is expressed by general formula (4)

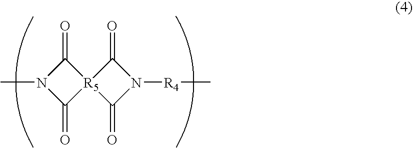

where R₅ is any one of 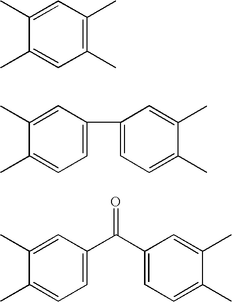
and R₄ is a divalent organic group expressed by 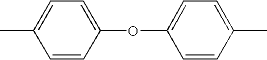
and/or

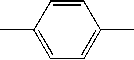

Further, in the polyimides, it is extremely preferred if the recurrent units expressed by general formulas (5) to (8) are contained:

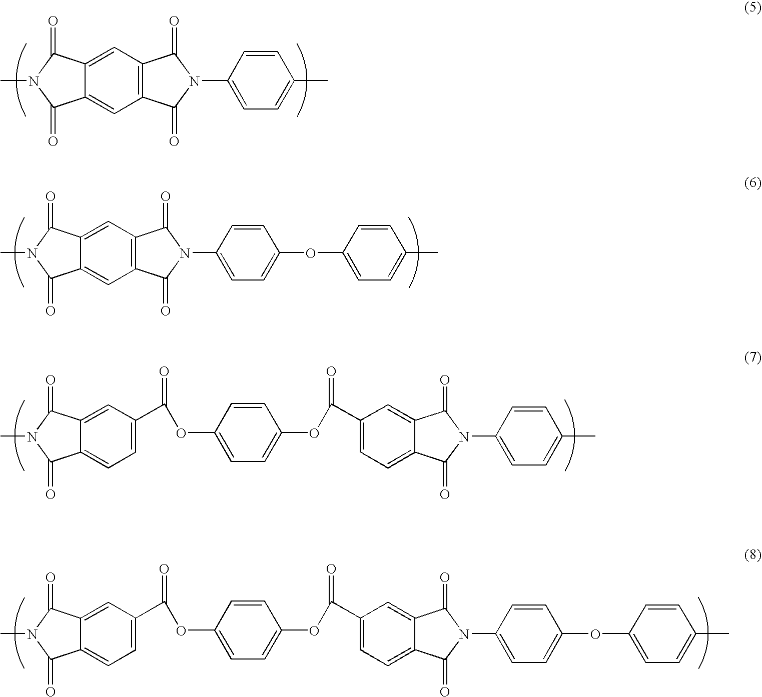

The polyimides are obtained by reacting acid dianhydride components with diamine components of a substantially equal amount in moles in an organic solvent, preparing a polyamic-acid dissolved in an organic solvent which is a precursor of polyimide, mixing it with a catalyst and a dehydrating agent, then flow-casting the mixture on a support base, and drying/heating it.

Under this circumstance, in the polyimide used to form a polyimide film of the present invention including the foregoing arrangement, paraphenylenediamine and diaminodiphenylether as diamine components each account for, preferably, not less than 25 mole %, more preferably not less than 25 mole % and not more than 75 mole %, and even more preferably not less than 33 mole % and not more than 66 mole %, of all the diamine components.

Further, in the polyimide used to form a polyimide film of the present invention including the foregoing arrangement, pyromellitic acid dianhydride as an acid dianhydride component accounts for, preferably, not less than 25 wt % of all the acid components, more preferably, not less than 33 wt %.

A polyimide film suited for use as a base film for a FPC is obtainable by using at least either one, preferably both, of these diamine components and the acid dianhydride component in the aforementioned range(s).

Further, in the polyimide used to form a polyimide film of the present invention including the foregoing arrangement, it is preferred if (a+b)/s, (a+c)/s, (b+d)/s, and (c+d)/s all fall in a range of 0.25 to 0.75, where a, b, c, and d are the respective numbers of units, expressed by general formulas (5) to (8), which appear recurrently in molecules, and s=a+b+c+d.

A polyimide film more suited for use as a base film for a FPC is obtainable by controlling the number of recurrent units in molecules, and more preferably by, as well as the controlling of the number of recurrent units in molecules, using the diamine components and the acid dianhydride component in the foregoing range(s).

Specifically, a polyimide film is obtainable with a water absorbency of not more than 2.0%, a linear swelling coefficient (100° C. to 200° C.) of not more than 20 ppm/° C., a moisture-absorption swelling coefficient of not more than 10 ppm/% RH, an elastic modulus of not less than 4.0 GPa and not more than 8.0 GPa, and a tension elongation ratio of not less than 20%, by controlling the amounts at which the diamine components/acid dianhydride component are used and/or the number of recurrent units in molecules. If the amounts of the diamine components/acid dianhydride component are used and/or the number of recurrent units in molecules falls out of the foregoing ranges, most often resultant polyimide films do not exhibit the foregoing properties and are extremely difficult to use and fabricate as base films for FPCs.

Now, the following will describe a method of manufacturing the foregoing polyimide films used suitably in the present invention, i.e., the aforementioned organic-insulating-layer-forming step which is part of the manufacturing method of the present invention.

Examples of organic solvents used in polymerizing the polyamic-acid include ureas, such as tetramethylurea and N,N-dimethyl ethylurea; sulfoxides and sulfones, such as dimethylsulfoxide, diphenylsulfone, and tetramethylsulfone; aprotic solvents of amides and phosphoryl amides, such as N,N-methylacetamide, N,N-dimethylformamide, N,N′-diethyl N-methyl -2-pyrolidone, γ-butyllactone, and hexamethylphosphoric triamide; alkyl halides, such as chloroform and methylene chloride; aromatic hydrocarbons, such as benzene and toluene; phenols, such as phenol and cresol; and ethers, such as dimethylether, diethylether, and p-cresolmethylether. Typically, any one of the solvents is used alone; alternatively, two or more of them may be used together where necessary.

Commercially available organic solvents of the super-high or first grade as such may be used as the organic solvent in the present invention. Alternatively, they may be used after dehydration refining by means of dry distillation or another common process.

The polyamic-acid dissolved in an organic solvent may be prepared by any method, e.g., by polymerizing a polyamic-acid by a commonly known and used method using any of the organic solvents. Japanese Laid-open Patent Application 9-235373/1997 or Tokukaihei 9-235373 discloses a specific example of the polymerization method of obtaining a polyimide having high elasticity, low thermal swelling coefficient, and low water absorbency. The polymerization can be carried out according to the technology.

The polyamic-acid is polymerized, typically, in two stages. Specifically, a polyamic-acid of low viscosity called prepolymer is polymerized in the first stage, which is followed by the second stage in which a polyamic-acid of high viscosity is obtained by adding the organic solvent dissolving an acid dianhydride.

A step is preferably interposed between the first and second stages, so as to remove insoluble material and foreign objects mixed up with prepolymer from prepolymer using a filter or the like. The step is capable of reducing foreign objects and defaults in the resultant polyimide film.

Specifically, the presence of defaults due to insoluble material and mixed-up foreign objects on a polyimide film surface would render adhesion insecure between the polyimide film and the metal layer 4 in the above-detailed step of forming a metal layer on a polyimide film (organic insulating layer 2) surface and causes an alkaline etching solution to seep down through areas of poor adhesion in the step of alkaline etching (will be detailed later). A result could be a hole 3 (opening) which might be deformed or otherwise lacking desired features. For these reasons, insoluble material and foreign objects are preferably removed as much as possible.

The filter is not limited in any particular manner so long as it is capable of removing insoluble material and foreign objects. The filter has openings ½ or less times the polyimide film thickness, preferably ⅕ or less, and more preferably 1/10 or less.

The polyamic-acid dissolved in an organic solvent contains not less than 5 wt % and not more than 40 wt % polyamic-acid, preferably not less than 10 wt % and not more than 30 wt %, and more preferably not less than 13 wt % and not more than 20 wt %, in the organic solvent. The organic solution of a polyamic-acid preferably satisfies one of these conditions for easy handling. The polyamic-acid preferably has an average molecular weight of 10,000 or more for improved polyimide film's physical properties and 1,000,000 or less for easy handling.

The polyimide film may be fabricated from the polyamic-acid dissolved in an organic solvent in any manner: typical examples are thermal ring closing methods (or simply “thermal methods”) in which dehydration ring closure is thermally achieved and chemical ring closing methods (or simply “chemical method”) in which a dehydrating agent is used.

A thermal ring closing method is taken as an example for specific illustration: Flow-cast the aforementioned polyamic-acid dissolved in an organic solvent (containing no dehydrating agent or catalyst) from a slit-equipped metal cap onto a drum, an endless belt, or another support base and mold it into a film. Then, heat-dry the film on the support base for 1 to 20 minutes at 200° C. or a lower temperature to obtain a self-supporting gel film. Pull the gel film off the support base.

Subsequently, fix both ends of the gel film and heat gradually or in stages from 100° C. to about 600° C. to encourage imidization. Then, cool down gradually and detach the film by unfixing their ends, so that a polyimide film of the present invention is obtained.

Next, a chemical ring closing method is taken as an example for specific illustration: First, prepare a mixed solution by adding stoichiometric or greater amounts of a dehydrating agent and a catalyst to the polyamic-acid dissolved in an organic solvent. Flow-cast the mixed solution from a slit-equipped metal cap onto a drum, an endless belt, or another support base and mold it into a film. Then, heat-dry the film on the support base for 1 to 20 minutes at 200° C. or a lower temperature to obtain a self-supporting gel film. Pull the gel film off the support base.

Subsequently, fix both ends of the gel film and heat gradually or in stages from 100° C. to about 600° C. to encourage imidization. Then, cool down gradually and detach the film by unfixing their ends, so that a polyimide film of the present invention is obtained.

The dehydrating agent used in the chemical ring closing method is not limited in any particular manner: common examples include aliphatic anhydrides, such as acetic anhydrides, and aromatic anhydrides. Similarly, the catalyst used in the chemical ring closing method is not limited in any particular manner: examples include aliphatic tertiary amines, such as triethyl amine; aromatic tertiary amines, such as dimethyl aniline; and heterocyclic tertiary amines, such as pyridine and isoquinoline.

The dehydrating agent and catalyst contents, relative to the polyamic-acid, varies depending on the structural formula from which the polyamic-acid is constructed. The ratio of the dehydrating agent to the amide groups in the polyamic-acid, both measured in moles, is preferably in a range of not less than 0.01 and not more than 10. The ratio of the catalyst to the amide groups in the catalyst and the polyamic-acid, both measured in moles, is preferably in a range of not less than 0.01 and not more than 10. Further, The ratio of the dehydrating agent to the amide groups in the polyamic-acid, both measured in moles, is more preferably in a range of not less than 0.5 and not more than 5. The ratio of the catalyst to the amide groups in the catalyst and the polyamic-acid, both measured in moles, is more preferably in a range of not less than 0.5 and not more than 5. In these “more preferable” cases, a gelation retardant, for example, acetyl acetone, may be used together.

The dehydrating agent and catalyst contents, relative to the polyamic-acid, may be determined by means of the time it takes for viscosity to start to rise after the polyamic-acid is mixed with the dehydrating agent/catalyst mixture at 0° C. (pot life). Typically, it is preferred if the pot life is in a range of not less than 0.5 minutes and not more than 20.

In the chemical ring closing method, the step of removing the insoluble material and mixed-up foreign objects using a filter or the like is carried out before mixing the dehydrating agent and the catalyst with the polyamic-acid dissolved in an organic solvent.

In the present invention, it is preferable to employ the chemical ring closing method to obtain a polyimide film, in which case the obtained polyimide film will boast excellent mechanical properties, such as elongation ratio and tension resistance. Adopting the chemical ring closing method is also advantageous in that imidization takes less time. The present invention is by no means limited to the chemical ring closure method: a thermal ring closing method may be used alone, or alternatively the chemical ring closing method may be used together with a thermal ring closing method.

Irrespective of whichever method may be employed, a thermal ring closing method or a chemical ring closing method, the polyamic-acid dissolved in an organic solvent may contain various additives where necessary. Specific examples of such additives include oxidation inhibitors, photostabilizers, fire retardants, electric charge inhibitors, thermal stabilizers, ultraviolet ray absorbers, inorganic fillers, and various reinforcers.

The method of manufacturing a wiring board of the present invention includes an etching step to etch the organic insulating layer 2. The organic insulating layer 2 etched in the etching step is a polyimide film made of at least a polyimide containing the recurrent unit expressed by general formula (1) above. In the etching, an etchant is used which is made up of oxyalkylamine, a hydroxide of an alkaline metal compound, water, and an aliphatic alcohol: the inclusion of an aliphatic alcohol is optional, but preferred.

Specific, preferred examples of the oxyalkylamine which is part of the etchant include primary amines, such as ethanolamines, propanolamines, butanolamines, and N(a-aminoethyl)ethanolamines; and secondary amines, such as diethanolamines, dipropanolamines, N-methylethanolamines, and N-ethylethanolamines. Any one of these oxyalkylamines may be used alone, or alternatively two or more of them may be used together in any combination. Especially preferred among the listed oxyalkylamines is 2-ethanolamine.

Preferred examples of the hydroxide of an alkaline metal compound which is part of the etchant include potassium hydroxide, sodium hydroxide, and lithium hydroxide. Any one of these hydroxides of alkaline metal compounds may be used alone, or alternatively two or more of them may be used together in any combination. Especially preferred among the listed compounds is potassium hydroxide.

This etchant composition gives etchants containing at least the aforementioned recurrent unit expressed by general formula (1), which can be used solely in the etching of polyimides. Consequently, as will be discussed later in detail, the holes 3 of desired shape can be surely and efficiently fabricated on the wiring board.

The oxyalkylamine concentration in the whole etchant is preferably in a range of not less than 10 wt % and not more than 40 wt %, and more preferably in a range of not less than 15 wt % and not more than 35 wt %. Especially, when 2-ethanolamine is used as the oxyalkylamine, its concentration in the whole etchant is preferably in a range of not less than 55 wt % and not more than 75 wt %.

The concentration of the hydroxide of an alkaline metal compound in the whole etchant is preferably in a range of not less than 10 wt % and not more than 40 wt %, and more preferably in a range of not less than 15 wt % and not more than 35 wt %. Especially, when potassium hydroxide is used as the hydroxide of an alkaline metal compound, its concentration in the whole etchant is preferably in a range of not less than 20 wt % and not more than 30 wt %.

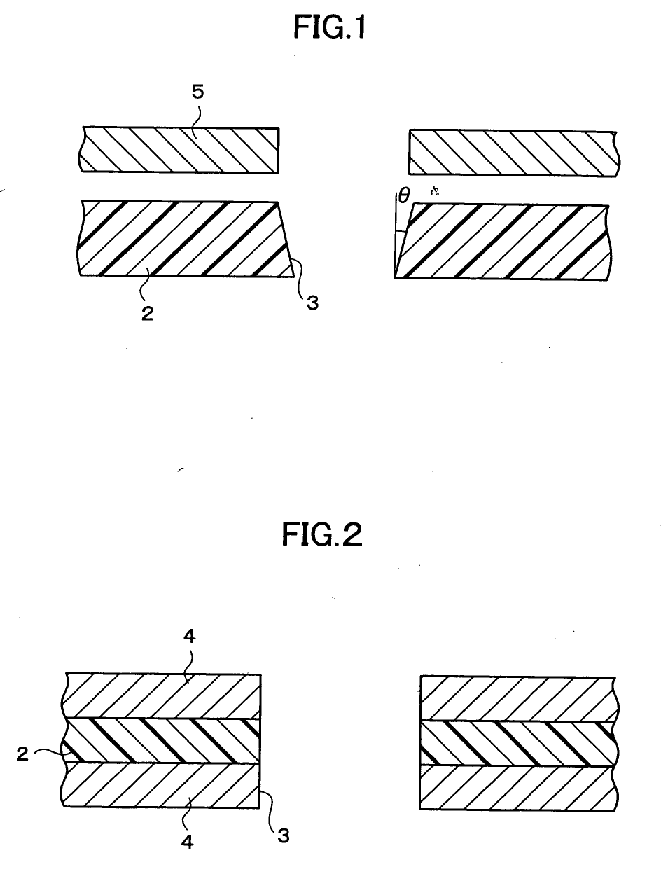

Adding too much of the 2-ethanolamine and the hydroxide of an alkaline metal compound is not preferable. If either one or both of their concentrations fall far below or above the specified range, performance (etching speed) drops; the 2-ethanolamine decomposes, the etchant's viscosity rises, resulting in clogging of the piping and the like; the holes (openings) 3 formed in the polyimide are distorted and have increased taper angle (see FIG. 1).

As mentioned in the foregoing, the etchant of the present invention preferably contains an aliphatic alcohol. Specific examples of the aliphatic alcohol suitable for use include methanol, ethanol, isopropyl alcohol, and other lower alcohols having 5 or less carbon atoms. Any of these aliphatic alcohols may be used alone, or alternatively two or more of them may be mixed together in any combination for use where necessary.

The aliphatic alcohol(s) may be added at any ratio. The ratio of the aliphatic alcohol to the water in the etchant is preferably in a range of 2/8 to 8/2 in weight. Further, the concentration of the aliphatic alcohol/water mixture to the whole etchant is preferably in a range of not less than 40 wt % and not more than 60 wt %. Ratios of the aliphatic alcohol to the water which are far below or above the specified range are not desirable, because such ratios may cause performance (etching speed) may drop.

The etchant of the present invention may be dissolved in an organic solvent where necessary.

In the etching step of the method of manufacturing a wiring board of the present invention, etching conditions are not limited in any particular manner, so long as the aforementioned polyimide film is etched using the etchant to form holes 3 with a predefined taper angle. It is, however, preferred if the step meets the following requirements, among others, as to an etching mask and etching temperature.

Etching temperature is preferably in a range of not less than 50° C. and not more than 90° C., more preferably in a range of not less than 60° C. and not more than 80° C., and even more preferably in a range of not less than 65° C. and not more than 75° C. Carrying out the etching step in the specified temperature range does not cause a drop in performance (etching speed) and allows for sufficient control over the taper angle of the holes 3 formed through the polyimide film.

The mask 5 used in the etching step is made of a material which is resistant to the etchant. Any alkali-resistant mask (alkali-resistant etching mask) may be used. Especially, in the present invention, the mask 5 may be metal coatings formed on the polyimide film (organic insulating layer 2). More specifically, the above-detailed metal layer 4 may be used as the mask 5.

As mentioned earlier, the metal layer 4 formed on the surface of the polyimide film (organic insulating layer 3) plays dual roles as a metal wiring layer and an alkali-resistant mask layer. Therefore, no dedicated mask 5 needs to be separately provided in the etching of the polyimide film, and improved efficiency is achieved in the method of manufacturing a wiring board of the present invention.

The etching technique used in the present invention is not limited in any particular manner. Preferable, specific techniques are: (1) “Dip technique” whereby the stacked layer entity (organic insulating layer 2/metal layer 4) is dipped in the etchant. (2) “Spray technique” whereby the stacked layer entity is sprayed with the etchant.

In the present invention, these techniques can be used in combination with (3) ultrasound irradiation and/or (4) etchant stirring, so as to improve etching performance and provide a preventive measure against etchant degradation. Alternatively, technique (1), or dip technique, may be used in combination with technique (2), or spray technique: specifically, the stacked layer entity dipped in the etchant and sprayed with the etchant (technique (5) or “dip & spray technique”). Any of these techniques may be used where appropriate. In applying technique (5), or dip & spray technique, after the stacked layer entity is dipped in the etchant, the etchant is preferably sprayed onto areas of the stacked layer entity where the entity is etched, using a spray nozzle or other spray means, at a pressure of 0.5 kg/cm² or more.

The above-detailed method of manufacture is capable of forming multiple holes (openings) 3 through the organic insulating layer made of a polyimide film so that the holes 3 meet following requirements:

(1) The wall of each hole 3 is positioned at 45° or less, preferably 5° or less, to the axis of the hole 3, that is, the taper angle is 45° or less, preferably 5° or less, as illustrated in FIG. 1.

(2) The length across which edge profile deformation occurs in each hole 3 is less than the thickness of the organic insulating layer 3 (polyimide film).

(3) The holes 3 are formed circular, 0.5 mm in diameter, and 5 or less of the holes 3 has an edge profile deformation which is 10% or more as long as the organic insulating layer 3 is thick.

The polyimide used in the present invention therefore must be capable of being etched with the etchant and satisfy requirements (1) to (3) in the etching step: specifically, polyimides expressed by the aforementioned general formula fall in this category. The polyimide film is made of one of these polyimides as mentioned earlier.

Occurrence of edge profile deformation is restrained in the holes 3 formed in the etching step. Edge profile deformation refers to an undesirable, disturbed edge profile of an etched-out hole 3 which may occur in alkaline etching the organic insulating layer 2, presumably due to etchant reaching an interface between the organic insulating layer 2 and the metal layer 4 (metal wiring layer). Conventionally edge profile deformation could not be restrained effectively.

In contrast, the method of manufacture of the present invention performs etching which is capable of delivering particular shapes precisely as required, by etching a specified polyimide with a specified etchant.

An ordinary etchant gradually etches away the surface of the polyimide film. The result is that the obtained hole gets narrower as it gets deeper. Consequently, the interior, wall of the hole 3 is not parallel to the axis of the obtained hole 3, that is, the hole 3 tapers, even if, ideally, the interior wall of the obtained hole 3 is upright and parallel to the axis of the hole 3. The phenomenon is an issue both in wet technology and dry technology.

In contrast, the present invention employs a specified polyimide and a specified etchant, enabling good control of the etching. Consequently, the holes 3 can be formed in desired shape, and the occurrence of etching profile deformation to the obtained holes 3 can be well avoided.

The polyimide film (organic insulating layer 3) of the present invention has a thickness in a range of not less than 5 μm and not more than 75 μm. Therefore, it can be said that the method of manufacturing a wiring board of the present invention provides a good method of etching a polyimide film of such thickness.

The hole 3 formed by the method of manufacture of the present invention only needs to pierce the polyimide film, and its diameter is not limited in any particular manner. In the present invention, minuscule holes 3 can be formed with a diameter equal to, or less than, 100 μm.

The range of the taper angle of the hole 3 is not limited in any particular manner. With the method of manufacture of the present invention, the taper angle also becomes capable of being controlled, because the method is capable of forming the holes 3 while controlling the etching of the polyimide in a satisfactory manner. Typically, the taper angle of the wall of the hole 3 to the axis of the hole 3 may assume a value equal to, or less than, 45°, preferably a value equal to, or less than, 5°, depending on the utility of the wiring board, e.g., whether the board is used as FPC.

As detailed in the foregoing, the wiring board of the present invention has a metal wiring layer and an organic insulating layer which is made of a polyimide film. The organic insulating layer is provided with openings, and the taper angle of the wall of each opening to the axis of the opening is 45° or less.

In other words, the method of manufacturing a wiring board of the present invention at least forms the openings by alkaline etching through the organic insulating layer on a wiring board made up of a metal wiring layer and an organic insulating layer which is made of a polyimide film, so that the taper angle of the wall of each opening to the axis of the opening is 45° or less.

This makes it possible to extremely efficiently form holes in desired shape through a polyimide-made organic insulating layer without developing any edge profile deformation. Consequently, holes, such as via holes and through holes, can be formed efficiently in desired shape through an organic insulating layer on a wiring board.

The following will discuss preferable embodiments of the present invention in reference to examples and comparative examples, which are by no means limiting to the present invention. A person skilled in the art could make various changes, alterations, and modifications in reducing the present invention into practice, all without departing from the spirit and scope of the present invention. In the description below, compounds will be referred to by abbreviations where necessary. The abbreviations will be given in parentheses immediately following the first appearance.

### METHOD EXAMPLE 1

### How to Prepare Polyimide Film

A reactor was charged with dimethylformamide (DMF), 5 equivalent amounts of 4,4′-diaminodiphenylether (ODA), and 5 equivalent amounts of paraphenylenediamine (p-PDA) and stirred until the ODA and the p-PDA were completely dissolved. The reactor was then further charged with 1,4-hydroquinone dibenzoate-3,3′ and 5 equivalent amounts of 4,4′-tetracarboxylic acid dianhydride (TMHQ) and stirred 90 minutes. The reactor was charged further with 4.5 equivalent amounts of pyromellitic anhydride (PMDA) and stirred 30 minutes.

Thereafter, a DMF solution of 0.5 equivalent amounts of PMDA was gradually added and cooled 60 minutes while stirring, so as to prepare a DMF solution of a polyamic-acid. The amount of the DMF used was adjusted so that the diamine component and the acid dianhydride component, when combined, accounts for 15 wt % of the polyamic-acid dissolved in the organic solvent.

Next, the DMF solution of the polyamic-acid was mixed with an acetic anhydride (AA), isoquinoline (IQ), and DMF. The mixture was extruded from a die and cast on an endless belt. It was then heat-dried on the endless belt to prepare a self-supporting green sheet. Note that the heat-drying was carried out until the weight of volatile components in the mixture is 50% that of the film after baking.

Thereafter, the green sheet was peeled off the endless belt. The endless sheet was fixed at both ends to a pin sheet which moved continuously, so that it was transported to heating ovens where it was heated at 200° C., 400° C., and 530° C. respectively. Then, it was slowly cooled down to room temperature in a lehr to form a polyimide film. Then the polyimide film was peeled off the pin sheet as it was moved out of the lehr. Note that the film thickness was set to 25 μm.

The following properties of the obtained polyimide film were measured.

(1) Linear Swelling Coefficient

Variations of the linear swelling coefficient were measured across the 100° C.-200° C. temperature range, using a TMA apparatus manufactured by Rigaku Electric Co. Ltd. under a nitrogen flow with a temperature profile of 20 to 400° C., 10° C./min. Results showed that the linear swelling coefficient was 12 ppm/° C.

(2) Elastic Modulus and Elongation Ratio

The properties were measure according to ASTM-D-882. The elastic modulus was 5.8 GPa, and the elongation ratio was 45%.

(3) Moisture-absorption Swelling Coefficient

Using the aforementioned measuring instrument (see FIG. 3), the polyimide film was left for 24 hours in a 50° C. 30% RH environment and checked to ensure that the film dimensions remained unchanged, before being let left for 24 hours in a 50° C. 80% RH environment. The film dimensions were measured to calculate the moisture-absorption swelling coefficient according to formula (2) above (see FIG. 4 for humidity variations). The length (elongation) was measured using a TMA (TMC -140) manufactured by Shimadzu Corporation (calculation temperature: 50° C.). Results showed that the moisture-absorption swelling coefficient was 7 ppm/% RH.

(4) Water Absorbency

The water absorbency was calculated according to formula (3) above, W1 being the weight of a film which was dried at 150° C. for 30 minutes, and W2 being the weight of the film which was dipped in distilled water for 24 hours and wiped to remove water drops from its surface. Results showed that the water absorbency was 1.2%.

Next, a wiring board of the present invention and a comparative wiring board were prepared from the polyimide film obtained in method example 1 and evaluated with respect to the etching condition of the organic insulating layers (polyimide films). Description of a specific valuation method follows.

[Etching Condition Evaluation]

(I) Taper Angle θ

The front surface of each of the obtained wiring boards was imaged using a microscope, and the diameter of the hole through the polyimide film was measured at the top (close to the front surface) and at the bottom (close to the back surface). The taper angle θ was calculated from the diameter values and the thickness of the polyimide film.

(II) Occurrence of Overetching

The surface of each wiring board (1) was observed by SEM from an oblique direction. It was visually inspected to see if the hole diameter was smaller at the top than at the bottom. If it was, overetching was regarded as having occurred.

(III) Hole Edge Profile Deformation

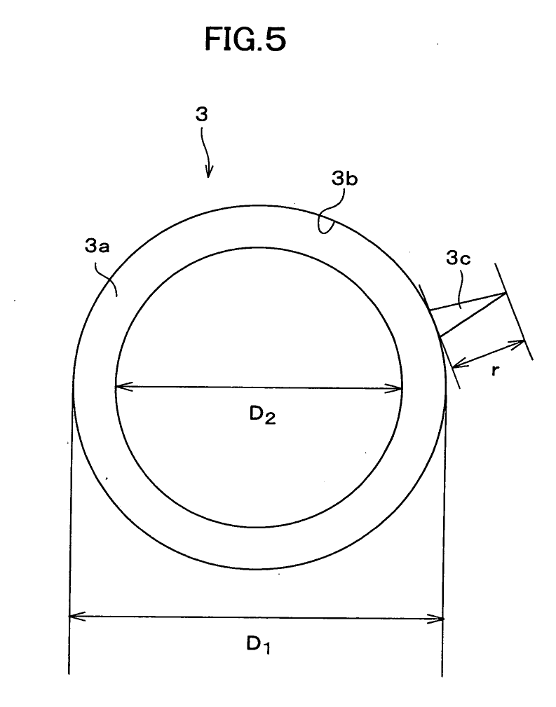

The hole 3 formed through the polyimide film (organic insulating layer 2) by etching was observed using a microscope from a vertical direction; it was a circular opening, as schematically shown in FIG. 5. If the hole 3 had a taper 3a, the diameter of the hole 3 would be greater at the top than at the bottom (D1 is the diameter value measured at the top, which appears in the upper part of FIG. 1, i.e., near end in etching; D2 is the diameter value measured at the bottom, which appears in the lower part of FIG. 1, i.e., far end or rear end in etching).

Accordingly, if the top-end edge 3b of the hole 3 did not follow an ideal circle, with a projection extending outward, the projection was recognized as an edge profile deformation 3c. The depth of the edge profile deformation 3c from the edge 3a was defined and measured as the length, r, of the edge profile deformation.

(IV) Number of Holes with Edge Profile Deformation

The thickness (25 μm) of the polyimide film was compared with the length, r, of the edge profile deformation to see which is greater. Among the holes with a diameter D=0.5 mm, three holes had an edge profile deformation of which the length r was equal to, or greater than, the thickness (25 μm) of the polyimide film.

### EXAMPLE 1

The polyimide film obtained by polyimide preparation method example 1 was attached onto a aluminum board using polyimide tape, so that it would constitute an organic insulating layer. Thereafter, a thin chromium film layer (first metal layer) and a thin copper film layer (second metal layer) were concurrently vapor deposited on the polyimide layer, using a sputtering device (sputtering system manufactured by Shimadzu Corporation; product name HSM-720). A metal layer which was made up of the chromium layer and the copper layer was thus formed on one surface of the aluminum board.

In the sputtering, argon as a sputtering ion source was introduced into a chamber. The chromium layer was vapor deposited at 1×10⁻² Torr, 0.2 A, for 90 seconds; the obtained chromium layer was about 500 Å thick. As the vapor deposition for copper, conditions were 5×10⁻³ Torr, 0.5 A, and 60 minutes; the obtained copper layer was about 7 μm thick.

Thereafter, the aluminum board was turned over and placed in a vacuum so that the back wide was subjected to vapor deposition to form a chromium layer and a copper layer thereon, as was the case with the front surface. Hence, the aluminum board was provided with vapor-deposited chromium and copper layers on each surface. The aluminum board was left at room temperature for a whole day and night to make the vapor-deposited copper layer stable. The board thus produced will be referred to as stacked layer entity (1).

Masking tape was attached to a surface of stacked layer entity (1). A photoresist was applied to the other surface and exposed to light using a mask having circular holes measuring 0.5 mm in diameter. After alkaline development, only the copper layer was etched with a ferric chloride/hydrochloric acid etchant to form the metal wiring layer. The mask was peeled using a peeling liquid.

The chromium layer was dissolved in a potassium permanganate/sodium hydroxide solution, then reduced in a water solution of oxalic acid and etched, so as to form circular holes measuring 0.5 mm in diameter on the copper layer surface. Stacked layer entity (1) with the holed copper layer will be henceforth referred to as sample (1).

A water solution of potassium hydroxide and 2-ethanolamine was prepared as an etchant, so as to provide a mixture ratio in weight, (potassium hydroxide) (2-ethanolamine): (water)=1:2.5:0.5.

The metal layer of sample (1) was dipped in the etchant for 3 minutes to etch the polyimide layer; the temperature of the etchant was specified to 68° C. After the etching, sample (1) was washed in water to remove residual etchant from the polyimide layer.

After the etching, sample (1) was etched in a ferric chloride/hydrochloric acid etchant to remove the copper layer. Wiring board (1) of the present invention was thus obtained. Wiring board (1) was inspected to measure its taper angle and see occurrence/non-occurrence of overetching; results are listed in table 1 in columns (I) and (II) respectively.

For comparing purposes, table 1 lists whether the board was subjected to plasma processing and the composition of the etchant used, as well as (I) and (II). Note that KOH is potassium hydroxide, H₂O water, EtOH ethanol, and 2-EA ethanolamine. Referring to column (II) in the table, “x” indicates that no holes through the polyimide film were formed in the etching.

### COMPARATIVE EXAMPLE 1

Comparative wiring board (1) was prepared in the same manner as in example 1 above, except that the etchant used was a water solution prepared so as to provide a mixture ratio in weight, (potassium hydroxide): (2-ethanolamine): (water)=1:0:3. Comparative wiring board (1) was inspected to measure its taper angle and see occurrence/non-occurrence of overetching; results are listed in table 1 in columns (I) and (II) respectively.

### COMPARATIVE EXAMPLE 2

Comparative wiring board (2) was prepared in the same manner as in example 1 above, except that the etchant used was a water solution prepared to provide a mixture ratio in weight, (potassium hydroxide) (2-ethanolamine): (water)=1:0.5:2.5. Comparative wiring board (2) was inspected to measure its taper angle and see occurrence/non-occurrence of overetching; results are listed in table 1 in columns (I) and (II) respectively.

### COMPARATIVE EXAMPLE 3

Comparative wiring board (3) was prepared in the same manner as in example 1 above, except that the etchant used was a water solution prepared to provide a mixture ratio in weight, (potassium hydroxide) (2-ethanolamine): (water)=1:1:2. Comparative wiring board (3) was inspected to measure its taper angle and see occurrence/non-occurrence of overetching; results are listed in table 1 in columns (I) and (II) respectively.

### COMPARATIVE EXAMPLE 4

Comparative wiring board (4) was prepared in the same manner as in example 1 above, except that the etchant used was a water solution prepared to provide a mixture ratio in weight, (potassium hydroxide) (2-ethanolamine): (water)=1:1.5:1.5. Comparative wiring board (4) was inspected to measure its taper angle and see occurrence/non-occurrence of overetching; results are listed in table 1 in columns (I) and (II) respectively.

### COMPARATIVE EXAMPLE 5

Comparative wiring board (5) was prepared in the same manner as in example 1 above, except that the etchant used was a water solution prepared to provide a mixture ratio in weight, (potassium hydroxide) (2-ethanolamine): (water)=1:2:1. Comparative wiring board (5) was inspected to measure its taper angle and see occurrence/non-occurrence of overetching; results are listed in table 1 in columns (I) and (II) respectively.

### EXAMPLE 2

Wiring board (2) of the present invention was prepared in the same manner as in example 1 above, except that the etchant used was a water solution of potassium hydroxide, ethanol, and 2-ethanolamine prepared so as to provide a mixture ratio in weight, (potassium hydroxide): (water): (ethanol): (2-ethanolamine)=1:0.4:1.6:1. Wiring board (2) was inspected to measure the taper angle and the hole edge profile deformation and to count the number of holes having developed an edge profile deformation; results are listed in table 1 in columns (I), (III), and (IV) respectively.

### COMPARATIVE EXAMPLE 6

Comparative wiring board (6) was prepared in the same manner as in example 3 above, except that the etchant used was a water solution prepared to provide a mixture ratio in weight, (potassium hydroxide): (water): (ethanol): (2-ethanolamine)=1:2:0:1. Comparative wiring board (6) was inspected to measure the taper angle and the hole edge profile deformation and to count the number of holes having developed an edge profile deformation; results are listed in table 1 in columns (I), (III), and (IV) respectively.

### COMPARATIVE EXAMPLE 7

Comparative wiring board (7) was prepared in the same manner as in example 3 above, except that the etchant used was a water solution prepared to provide a mixture ratio in weight, (potassium hydroxide): (water): (ethanol): (2-ethanolamine)=1:1.6:0.4:1. Comparative wiring board (7) was inspected to measure the taper angle and the hole edge profile deformation and to count the number of holes having developed an edge profile deformation; results are listed in table 1 in columns (I), (III), and (IV) respectively.

### COMPARATIVE EXAMPLE 8

Comparative wiring board (8) was prepared in the same manner as in example 3 above, except that the etchant used was a water solution prepared to provide a mixture ratio in weight, (potassium hydroxide): (water): (ethanol): (2-ethanolamine)=1:1:1:1. Comparative wiring board (8) was inspected to measure the taper angle and the hole edge profile deformation and to count the number of holes having developed an edge profile deformation; results are listed in table 1 in columns (I), (III), and (IV) respectively.

### EXAMPLE 3

Wiring board (3) of the present invention was prepared in the same manner as in example 2 above, except that the polyimide film was subjected to atmospheric pressure plasma processing before stacked on a surface of the aluminum board. Wiring board (3) was inspected to measure the taper angle and the hole edge profile deformation and to count the number of holes having developed an edge profile deformation; results are listed in table 1 in columns (I), (III), and (IV) respectively.

### COMPARATIVE EXAMPLE 9

Comparative wiring board (9) was prepared in the same manner as in example 4 above, except that the etchant used was a water solution prepared to provide a mixture ratio in weight, (potassium hydroxide): (water): (ethanol): (2-ethanolamine)=1:2:0:1. Comparative wiring board (9) was inspected to measure the taper angle and the hole edge profile deformation and to count the number of holes having developed an edge profile deformation; results are listed in table 1 in columns (I), (III), and (IV) respectively.

### EXAMPLE 4

Wiring board (4) of the present invention was prepared in the same manner as in example 3 above, except that the etchant used was a water solution prepared to provide a mixture ratio in weight, (potassium hydroxide) (water): (ethanol): (2-ethanolamine)=1:1.6:0.4:1. Wiring board (4) was inspected to measure the taper angle and the hole edge profile deformation and to count the number of holes having developed an edge profile deformation; results are listed in table 1 in columns (I), (III), and (IV) respectively.

### EXAMPLE 5

Wiring board (5) of the present invention was prepared in the same manner as in example 3 above, except that the etchant used was a water solution prepared to provide a mixture ratio in weight, (potassium hydroxide): (water): (ethanol): (2-ethanolamine)=1:1:1:1. Wiring board (5) was inspected to measure the taper angle and the hole edge profile deformation and to count the number of holes having developed an edge profile deformation; results are listed in table 1 in columns (I), (III), and (IV) respectively.

TABLE 1

| | | Composition of | | | | | | | |
|---|---|---|---|---|---|---|---|---|---|
| | Plasma | Etchant in Weight | | | | Results | | | |
| | Process | KOH | H₂O | EtOH | 2-EA | (I) | (II) | (III) | (IV) |
| Exam- | No | 1 | 0.5 | — | 2.5 | 0° | No | | |
| ple 1 | | | | | | | | | |
| Comp. | No | 1 | 3 | — | 0 | x | No | — | — |
| Ex. 1 | | | | | | | | | |
| Comp. | No | 1 | 2.5 | — | 0.5 | x | No | — | — |
| Ex. 2 | | | | | | | | | |
| Comp. | No | 1 | 2 | — | 1 | 27° | No | — | — |
| Ex. 3 | | | | | | | | | |
| Comp. | No | 1 | 1.5 | — | 1.5 | 22° | No | — | — |
| Ex. 4 | | | | | | | | | |
| Comp. | No | 1 | 1 | — | 2 | 20° | No | — | — |
| Ex. 5 | | | | | | | | | |
| Exam- | No | 1 | 0.4 | 1.6 | 1 | 33° | — | 0 μm | 0 |
| ple 2 | | | | | | | | | |
| Comp. | No | 1 | 2 | 0 | 1 | x | — | 90 μm | 14 |
| Ex. 6 | | | | | | | | | |
| Comp. | No | 1 | 1.6 | 0.4 | 1 | 23° | — | 40 μm | 10 |
| Ex. 7 | | | | | | | | | |
| Comp. | No | 1 | 1 | 1 | 1 | 24° | — | 30 μm | 7 |
| Ex. 8 | | | | | | | | | |
| Exam- | Applied | 1 | 0.4 | 1.6 | 1 | 33° | — | 0 μm | 0 |
| ple 3 | | | | | | | | | |
| Comp. | Applied | 1 | 2 | 0 | 1 | x | — | 90 μm | 14 |
| Ex. 9 | | | | | | | | | |
| Exam- | Applied | 1 | 1.6 | 0.4 | 1 | 23° | — | 0 μm | 0 |
| ple 4 | | | | | | | | | |
| Exam- | Applied | 1 | 1 | 1 | 1 | 24° | — | 0 μm | 0 |
| ple 5 | | | | | | | | | |

* Comp. Ex. < Comparative Example
Remarks: “x” indicates that no holes were formed through the polyimide film in the etching.

As would be clear from the results shown in table 1, the present invention is capable of forming well-shaped holes by an inexpensive, high performance alkaline etching method.

### METHOD EXAMPLE 2

### How to Prepare Polyimide Film

A reactor was charged with DMF and 1 equivalent amount of ODA, and stirred until the ODA was completely dissolved. The reactor was then further charged with 5 equivalent amounts of TMHQ and stirred 90 minutes. The reactor was charged further with 4.5 equivalent amounts of PMDA and stirred 30 minutes.

Thereafter, a DMF solution of 0.5 equivalent amounts of PMDA was gradually added and cooled 60 minutes while stirring, so as to prepare a DMF solution of a polyamic-acid. The amount of the DMF used was adjusted so that the diamine component and the acid dianhydride component, when combined, accounts for 15 wt % of the polyamic-acid dissolved in the organic solvent.

Next, the DMF solution of the polyamic-acid was mixed with AA, IQ, and DMF. The mixture was extruded from a die and cast on an endless belt. It was then heat-dried on the endless belt to prepare a self-supporting green sheet. Note that the heat-drying was carried out until the weight of volatile components in the mixture is 50% that of the film after baking.

Thereafter, the green sheet was peeled off the endless belt. The endless sheet was fixed at both ends to a pin sheet which moved continuously, so that it was transported to heating ovens where it was heated at 200° C., 400° C., and 530° C. respectively. Then, it was cooled down in a lehr in stages, 70° C. at a time, down to room temperature to form a polyimide film. Then the polyimide film was peeled off the pin sheet as it was moved out of the lehr. Note that the film thickness was set to 25 μm.

### EXAMPLE 6

The polyimide film obtained by polyimide preparation method example 2 was subjected to argon ion plasma processing as a pretreatment to remove unnecessary organic and other substances from the surfaces. Thereafter, a 50 Å thick chromium layer and a 2,000 Å thick copper layer were deposited as the first and second layers of the first metal layer, using a sputtering device “NSP-6” manufactured by Showa Vacuum Co., Ltd. Further, a copper layer was provided as the second metal layer by electric copper-sulfate plating (cathode current density 2A/dm²; plating thickness 20 μm). Thus, stacked layer entity (3) was obtained which included metal layers (chromium/copper/copper layers) on the polyimide film.

Masking tape was attached to a surface of stacked layer entity (3). A photoresist was applied to the other surface and exposed to light using a mask having circular holes measuring 0.5 mm in diameter. After alkaline development, only the copper layer was etched with a ferric chloride/hydrochloric acid etchant to form the metal wiring layer. The mask was peeled using a peeling liquid.

The chromium layer was dissolved in a potassium permanganate/sodium hydroxide solution, then reduced in a water solution of oxalic acid and etched, so as to form circular holes measuring 0.5 mm in diameter on the copper layer surface. Stacked layer entity (3) with the holed copper layer will be henceforth referred to as sample (3).

A water solution of potassium hydroxide, ethanol, and 2-ethanolamine was prepared as an etchant, so as to provide a mixture ratio in weight, (potassium hydroxide) (water): (ethanol): (2-ethanolamine)=1.0:1.6:0.4:1.0.

The metal layer of sample (3) was dipped in the etchant for 3 minutes to etch the polyimide layer; the temperature of the etchant was specified to 68° C. After the etching, sample (3) was washed in water to remove residual etchant from the polyimide layer.

After the etching, sample (3) was etched in a ferric chloride/hydrochloric acid etchant to remove the copper layer. Wiring board (6) of the present invention was thus obtained. Wiring board (6) was inspected to measure the taper angle and see occurrence/non-occurrence of overetching; results are listed in table 2 in columns (I) and (II) respectively.

Similarly to table 1, for comparing purposes, table 2 lists whether the board was subjected to plasma processing, the composition of the etchant used, and the type of the metal layers, as well as (I) and (II). Note that metal layer 1-1 is the first layer of the first metal layer and invariably 50 Å thick for all relevant examples; metal layer 1-2 is the first layer of the first metal layer and invariably 2,000 Å thick for all relevant examples; and metal layer 2 is the second metal layer and is invariably 20 μm for all relevant examples.

### EXAMPLE 7

Wiring board (7) of the present invention was prepared in the same manner as in example 6 above, except that the first layer of the first metal layer was nickel and that after alkaline development, the nickel layer and the copper layer were etched in a ferric chloride/hydrochloric acid etchant. Wiring board (7) was inspected to measure the taper angle and see occurrence/non-occurrence of overetching; results are listed in table 2 in columns (I) and (II) respectively.

### EXAMPLE 8

Wiring board (8) of the present invention was prepared in the same manner as in example 6 above, except that the first metal layer was 2,000 Å thick copper. Wiring board (8) was inspected to measure the taper angle and see occurrence/non-occurrence of overetching; results are listed in table 2 in columns (I) and (II) respectively.

### EXAMPLE 9

Wiring board (9) of the present invention was prepared in the same manner as in example 7 above, except that the etchant used was a water solution prepared to provide a mixture ratio in weight, (potassium hydroxide): (water): (ethanol): (2-ethanolamine)=1.0:0.4:1.6:1.0. Wiring board (9) was inspected to measure the taper angle and see occurrence/non-occurrence of overetching; results are listed in table 2 in columns (I) and (II) respectively.

### EXAMPLE 10

Wiring board (10) of the present invention was prepared in the same manner as in example 8 above, except that the etchant used was a water solution prepared to provide a mixture ratio in weight, (potassium hydroxide): (water): (ethanol): (2-ethanolamine)=1.0:0.4:1.6:1.0. Wiring board (10) was inspected to measure the taper angle and see occurrence/non-occurrence of overetching; results are listed in table 2 in columns (I) and (II) respectively.

### EXAMPLE 11

Wiring board (11) of the present invention was prepared in the same manner as in example 9 above, except that the etchant used was a water solution prepared to provide a mixture ratio in weight, (potassium hydroxide): (water): (ethanol): (2-ethanolamine)=1.0:0.4:1.6:1.0. Wiring board (11) was inspected to measure the taper angle and see occurrence/non-occurrence of overetching; results are listed in table 2 in columns (I) and (II) respectively.

### COMPARATIVE EXAMPLE 10

Comparative wiring board (10) was prepared in the same manner as in example 7, except that the etchant used was a water solution of potassium hydroxide and ethanol [1 mol potassium hydroxide per 1 m³ solution (=1N); and (water): (ethanol)=20:80] prepared under such conditions to enable alkaline etching to form holes through the polyimide film and also that the polyimide film was dipped for 50 minutes in the etchant of which temperature was specified to 40° C. for etching. Comparative wiring board (10) was inspected to measure the taper angle and see occurrence/non-occurrence of overetching; results are listed in table 2 in columns (I) and (II) respectively.

### COMPARATIVE EXAMPLE 11

Comparative wiring board (11) was prepared in the same manner as in example 7, except that the etchant used as a water solution of potassium hydroxide and ethanol [1 mol potassium hydroxide per 1 m³ solution (=1N); and (water): (ethanol)=20:80] prepared under such conditions to enable alkaline etching to form holes through the polyimide film and also that the polyimide film was dipped for 3 minutes in the etchant of which temperature was specified to 68° C. for etching. Comparative wiring board (11) was inspected to measure the taper angle and see occurrence/non-occurrence of overetching; results are listed in table 2 in columns (I) and (II) respectively.

TABLE 2

| | | Composition of | | | | Metal | | | | |
|---|---|---|---|---|---|---|---|---|---|---|
| | Plasma | Etchant in Weight | | | | Layers | | | Results | |
| | Process | KOH | H₂O | EtOH | 2-EA | 1-1 | 1-2 | 2 | (I) | (II) |
| Example 6 | Applied | 1.0 | 1.6 | 0.4 | 1.0 | Cr | Cu | Cu | 17° | No |
| Example 7 | Applied | 1.0 | 1.6 | 0.4 | 1.0 | Ni | Cu | Cu | 16° | No |
| Example 8 | Applied | 1.0 | 1.6 | 0.4 | 1.0 | Cu | | Cu | 17° | No |
| Example 9 | Applied | 1.0 | 0.4 | 1.6 | 1.0 | Cr | Cu | Cu | 1° | No |
| Example 10 | Applied | 1.0 | 0.4 | 1.6 | 1.0 | Ni | Cu | Cu | 0° | No |

| | | | | | | | | | |
|---|---|---|---|---|---|---|---|---|---|
| Example 11 | Applied | 1.0 | 0.4 | 1.6 | 1.0 | Cu | Cu | 0° | No |

| | | | | | | | |
|---|---|---|---|---|---|---|---|
| Comp. Ex. 10 | Applied | KOH& H₂O:EtOH | Cr | Cu | Cu | 81° | No |
| Comp. Ex. 11 | Applied | KOH& H₂O:EtOH | Cr | Cu | Cu | x | No |

* Comp. Ex. < Comparative Example
Remarks: “x” indicates that no holes were formed through the polyimide film in the etching.
Metal Layer 1-1: First Layer of First Metal Layer, Thickness = 50 Å
Metal Layer 1-2: First Layer of First Metal Layer, Thickness = 2,000 Å
Metal Layer 2: Second metal layer, Thickness = 20 μm

As would be clear from the results shown in table 2, the present invention is capable of forming well-shaped holes by an inexpensive, high performance alkaline etching method through the use of the above-detailed mask.

The specific embodiments and examples in Best Mode for Carrying out the Invention are included here purely for illustrative purposes, to clarify technical aspects of the present invention, and never intended to add limitations to the interpretation of the invention in any form. Variations are not to be regarded as a departure from the spirit and scope of the invention, and all such modifications are included within the scope of the following claims.

### INDUSTRIAL APPLICABILITY

As discussed in detail so far, the present invention is capable of forming holes, such as through holes and via holes in manufacturing a wiring board, by inexpensive, excellent performance method, termed alkaline etching. Therefore, the present invention is preferably applicable to the manufacture of printed wiring boards, especially, flexible printed wiring boards, and more particularly, to mounting of various components on printed wiring boards and manufacture of printed circuit boards.

1-38. (canceled)

39. A wiring board, comprising at least an organic insulating layer and a metal wiring layer,
wherein the organic insulating layer has an opening with a wall having a taper angle of not more than 45° with respect to the axis of opening; and
the organic insulating layer is a polyimide film made of a polyimide containing at least a recurrent unit expressed by general formula (1) 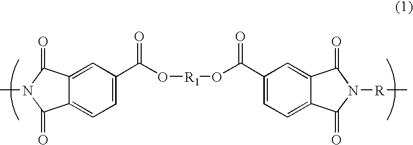
where R1 is an aromatic structure containing a benzene ring or a naphthalene ring and R is an aromatic structure containing a benzene ring.

40. The wiring board as defined in claim 39, wherein the taper angle is not more than 5°.

41. The wiring board as defined in claim 39, wherein the organic insulating layer is made of a polyimide.

42. A method of manufacturing a wiring board, comprising the step of forming an opening through an organic insulating layer of a wiring board which is made of at least the organic insulating layer and a metal wiring layer by alkaline etching, so that a wall of the opening wall has a taper angle of not more tan 45° with respect to an axis of the opening.

43. A wiring board for flexible printing, prepared by etching a polyimide film using an etchant containing at least water, an aliphatic alcohol, 2-ethanolamine, and an alkaline metal compound,
said wiring board meeting the following conditions:
(1) a wall of an opening formed has a taper angle of not more than 45° with respect to an axis of opening;
(2) in the opening, an edge profile deformation is not as long as the polyimide film is thick; and
(3) when two or more of the openings are formed in a circular shape measuring 0.5 mm in diameter, in not more than 5 of the openings, an edge profile deformation is not less than 10% as long as the polyimide film is thick.
